(19) United States
(12) Patent Application Publication
(10) Pub. No.: US 2026/0047393 A1
(43) Pub. Date: Feb. 12, 2026

(54) SUBSTRATE PROCESSING APPARATUS AND DIAGNOSIS METHOD

(71) Applicant: SEMES CO., LTD., Chungcheongnam-do (KR)

(72) Inventor: Sung Pil KIM, Hwaseong-si (KR)

(21) Appl. No.: 19/293,293

(22) Filed: Aug. 7, 2025

(30) Foreign Application Priority Data
Aug. 9, 2024 (KR) 10-2024-0106473

(51) Int. Cl. H01L 21/687; G01M 13/00; H01L 21/67

(52) U.S. Cl. CPC H01L 21/68728; G01M 13/00; H01L 21/67051

(57) ABSTRACT

Disclosed is an apparatus for processing a substrate, the apparatus including: a cup having a processing space with an open top; a spin chuck for supporting the substrate within the processing space; a liquid supply nozzle for supplying a processing liquid to the substrate supported on the spin chuck; and a chuck diagnosis jig for diagnosing a state of the spin chuck, in which the spin chuck includes: a body coupled to a rotary shaft; a plurality of chuck pins installed on the body and supporting a side of the substrate during a process; and a chuck pin driver for moving the plurality of chuck pins between a support position in which the plurality of chuck pins is in contact with an end of the substrate placed on the spin chuck and a standby position in which the plurality of chuck pins is spaced apart from the end of the substrate placed on the spin chuck.

### CROSS-REFERENCE TO RELATED APPLICATION

This application claims priority to and the benefit of Korean Patent Application No. 10-2024-0106473 in the Korean Intellectual Property Office on Aug. 9, 2024, the entire contents of which are incorporated herein by reference.

### TECHNICAL FIELD

The present invention relates to a substrate processing apparatus and a diagnosis method, and more particularly, to a substrate processing apparatus and a diagnosis method for diagnosing a state of a chuck pin.

### BACKGROUND ART

In order to manufacture a semiconductor device, a desired pattern is formed on a substrate through various processes, such as photography, etching, ashing, ion implantation, and thin film deposition. Various processing liquids are used in each process, and contaminants and particles are generated during the process. To solve this problem, a cleaning process for cleaning contaminants and particles is essentially performed before and after each process.

The cleaning process is performed by supplying the processing liquid in a state in which the substrate is placed on a spin chuck. In general, the substrate is loaded into a chamber from the outside and placed on the spin chuck. After that, the substrate proceeds with the process while being supported by the chuck pin.

However, when the process proceeds in a state where the substrate is not supported by the chuck pin, rides on the chuck pin, or the position of the substrate is out of position, there is a problem that causes defects in the substrate processing process. In order to prevent such a process defect, a method of diagnosing the state of the chuck pin before proceeding with the process on the substrate is needed.

### SUMMARY OF THE INVENTION

The present invention has been made in an effort to provide a substrate processing apparatus and a diagnosis method capable of efficiently processing a substrate.

The present invention has also been made in an effort to provide a substrate processing apparatus and a diagnosis method capable of diagnosing a state of a chuck pin before proceeding with a process for a substrate.

The objectives of the present disclosure are not limited thereto and other objectives not stated herein may be clearly understood by those skilled in the art from the following description.

An exemplary embodiment of the present invention, an apparatus for processing a substrate, the apparatus comprising: a cup having a processing space with an open top; a spin chuck for supporting the substrate within the processing space; a liquid supply nozzle for supplying a processing liquid to the substrate supported on the spin chuck; and a chuck diagnosis jig for diagnosing a state of the spin chuck, wherein the spin chuck includes: a body coupled to a rotary shaft; a plurality of chuck pins installed on the body and supporting a side of the substrate during a process; and a chuck pin driver for moving the plurality of chuck pins between a support position in which the plurality of chuck pins is in contact with an end of the substrate placed on the spin chuck and a standby position in which the plurality of chuck pins is spaced apart from the end of the substrate placed on the spin chuck, and the chuck diagnosis jig includes: a base part supportable by the spin chuck; and a pressure sensor for measuring a pressure value applied to the base part by the chuck pin when the plurality of chuck pins is driven from the standby position to the support position in a state where the chuck diagnosis jig may be placed on the spin chuck.

According to the exemplary embodiment of the present invention, wherein the base part may has the same diameter as the substrate supported on the spin chuck.

According to the exemplary embodiment of the present invention, wherein the pressure sensors may be provide at positions corresponding to the plurality of chuck pins in a number equal to a number of the plurality of chuck pins.

According to the exemplary embodiment of the present invention, wherein the chuck diagnosis jig further may include a display unit provided on the base part.

According to the exemplary embodiment of the present invention, wherein the display units are provided in a number equal to the number of the plurality of pressure sensors, and the plurality of pressure sensors may be installed in areas in which the plurality of display units is provided, respectively.

According to the exemplary embodiment of the present invention, wherein the plurality of pressure sensors and the plurality of display units may be provided at regular intervals along a circumferential direction of the base part.

According to the exemplary embodiment of the present invention, the apparatus may further include a controller for receiving a pressure value applied to the base part by each of the plurality of chuck pins from the plurality of pressure sensors and controlling the spin chuck and the display unit based on the plurality of pressure values.

According to the exemplary embodiment of the present invention, wherein the controller matches different colors according to magnitudes of the plurality of pressure values, and may controls the display unit to display the matched color.

According to the exemplary embodiment of the present invention, wherein the controller compares the plurality of pressure values with a preset value to determine whether there is a chuck pin that needs to be replaced among the plurality of chuck pins, controls the chuck pin driver when it is determined that all of the plurality of chuck pins need to be replaced, and, replaces a portion of the chuck pins or may controls mounting positions of the portion of the chuck pins when it is determined that the portion of the plurality of chuck pins needs to be replaced.

According to the exemplary embodiment of the present invention, wherein the display unit may be provided at a center of the base part.

According to the exemplary embodiment of the present invention, wherein the pressure sensor may be a resistive type pressure sensor or a capacitive type pressure sensor.

An exemplary embodiment of the present invention, a diagnosis method for a spin chuck that supports a substrate, the spin chuck comprising: a body; a plurality of chuck pins installed on the body and supporting a side of the substrate; and a chuck pin driver for moving the chuck pin between a support position in which the chuck pin is in contact with an end of the substrate placed on the spin chuck and a standby position in which the chuck pin is spaced apart from the end of the substrate placed on the spin chuck, the diagnosis method comprising: loading a chuck diagnosis jig onto the spin chuck; moving the chuck pin from the standby position to the support position in a state where the spin chuck is stopped; obtaining a first pressure value, which is a pressure value applied to the chuck diagnosis jig by each of the plurality of chuck pins; and performing diagnosis on the plurality of chuck pins based on the plurality of first pressure values.

According to the exemplary embodiment of the present invention, wherein the performing of the diagnosis on the plurality of chuck pins may include: matching the plurality of first pressure values with colors corresponding to the plurality of first pressure values; and displaying the matched color.

According to the exemplary embodiment of the present invention, wherein the performing of the diagnosis on the plurality of chuck pins based on the plurality of first pressure values may includes: comparing the plurality of first pressure values with a preset value and determining whether there is a chuck pin that needs to be replaced among the plurality of chuck pins; controlling the chuck pin driver when all of the plurality of chuck pins need to be replaced; and replacing a portion of the chuck pins when the portion of the plurality of chuck pins needs to be replaced.

According to the exemplary embodiment of the present invention, wherein the rotating of the spin chuck further may includes; obtaining a second pressure value, which is a pressure value applied to the chuck diagnosis jig by the plurality of chuck pins; and performing diagnosis on the plurality of chuck pins based on the plurality of second pressure values.

According to the exemplary embodiment of the present invention, wherein the performing of the diagnosis on the plurality of chuck pins based on the plurality of second pressure values may includes: comparing the plurality of second pressure values with a preset value and determining whether slip occurs in the plurality of chuck pins; and when the slip occurs in at least one of the plurality of chuck pins, controlling a mounting position of the at least one chuck pin.

An exemplary embodiment of the present invention, an apparatus for processing a substrate, the apparatus comprising: a cup having a processing space with an open top; a spin chuck for supporting the substrate within the processing space; a liquid supply nozzle for supplying a processing liquid to the substrate supported on the spin chuck; a chuck diagnosis jig for diagnosing a state of the spin chuck; and a controller for controlling the spin chuck and the chuck diagnosis jig, wherein the spin chuck includes: a body coupled to a rotary shaft; a plurality of chuck pins installed on the body and supporting a side of the substrate during a process; and a chuck pin driver for moving the plurality of chuck pins between a support position in which the plurality of chuck pins is in contact with an end of the substrate placed on the spin chuck and a standby position in which the plurality of chuck pins is spaced apart from the end of the substrate placed on the spin chuck, and the chuck diagnosis jig includes: a base part supportable by the spin chuck; and a pressure sensor for measuring a pressure value applied to the base part by the chuck pin when the plurality of chuck pins is driven from the standby position to the support position in a state where the chuck diagnosis jig is placed on the spin chuck; and a display unit provided in the base part, the base part has the same diameter as the substrate supported on the spin chuck, the pressure sensors are provided at positions corresponding to the plurality of chuck pins in a number equal to a number of the plurality of chuck pins, the display units are provided in a number corresponding a number of the plurality of pressure sensors, the plurality of pressure sensors is installed in areas in which the plurality of display units is provided, respectively, the plurality of pressure sensors and the plurality of display units are provided at regular intervals along a circumferential direction of the base part, and a controller receives a pressure value applied to the base part by each of the plurality of chuck pins from the plurality of pressure sensors and may controls the spin chuck and the chuck diagnosis jig based on the plurality of pressure values.

According to the exemplary embodiment of the present invention, wherein the controller matches different colors according to magnitudes of the plurality of pressure values, and may controls the display unit to display the matched color.

According to the exemplary embodiment of the present invention, wherein the controller compares the plurality of pressure values with a preset value to determine whether there is a chuck pin that needs to be replaced among the plurality of chuck pins, controls on the chuck pin driver when it is determined that all of the plurality of chuck pins need to be replaced, and, replaces a portion of the chuck pins or may controls a mounting position of the portion of the chuck pins when it is determined that the portion of the plurality of chuck pins need to be replaced.

According to the exemplary embodiment of the present invention, wherein the controller controls the spin chuck so that the spin chuck rotates, receives a pressure value applied to the base part by the plurality of chuck pins from the plurality of pressure sensors when the spin chuck rotates, determines whether slip occurs in the plurality of chuck pins based on the plurality of pressure values, and may controls a mounting position of at least one chuck pin when the slip occurs in the at least one of the plurality of chuck pins.

According to the exemplary embodiment of the present invention, a substrate may be efficiently processed.

According to the exemplary embodiment of the present invention, it is possible to diagnose the state of the chuck pin before proceeding with the processing of the substrate.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a top plan view of a liquid processing chamber provided in the substrate processing apparatus according to the exemplary embodiment of the present invention.

FIG. 3 is a top plan view for describing a spin chuck according to the exemplary embodiment of the present invention.

FIG. 4 is a perspective view of a chuck diagnosis jig according to the exemplary embodiment of the present invention.

FIG. 5 is a top plan view of the chuck diagnosis jig according to the exemplary embodiment of the present invention.

FIG. 6 is a flowchart of a diagnosis method according to an exemplary embodiment of the present invention.

FIGS. 7 to 14 are diagrams for describing the diagnosis method according to the exemplary embodiment of the present invention.

FIG. 15 is a top plan view of a chuck diagnosis jig according to another exemplary embodiment of the present invention.

FIG. 16 is a top plan view of a chuck diagnosis jig according to still another exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

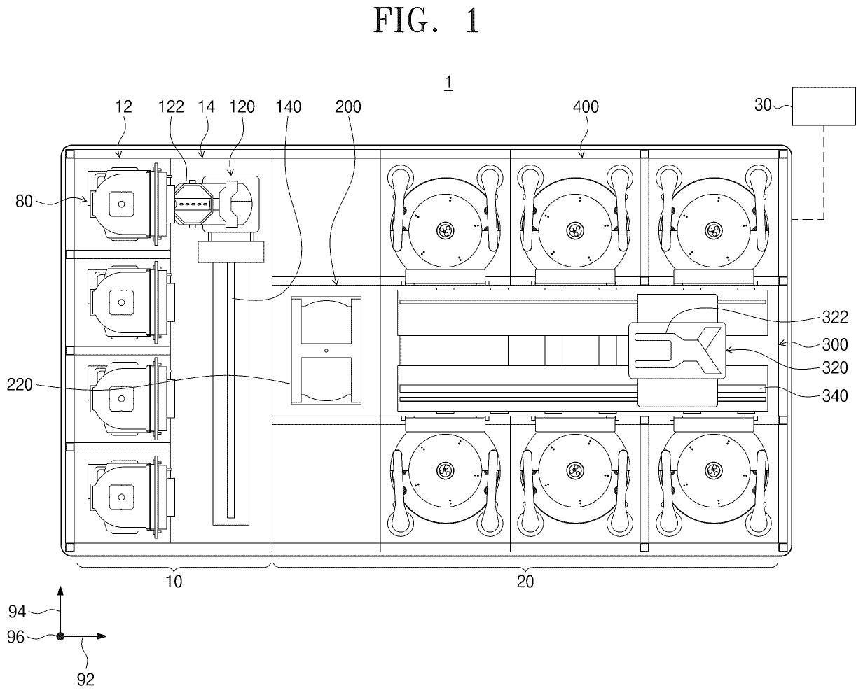

FIG. 1 is a top plan view of a substrate processing system according to an exemplary embodiment of the present invention.

Referring to FIG. 1, a substrate processing system includes an index module 10, a processing module 20, and a control module 30. According to an example, the index module 10 and the processing module 20 are disposed along one direction. Hereinafter, the direction in which the index module 10 and the processing module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the processing module 20, and makes the substrate W, which has been completely processed in the processing module 20, be accommodated in the container 80. A longitudinal direction of the index module 10 is provided in the second direction 94. The index module 10 includes a load port 12 and an index frame 14. Based on the index frame 14, the load port 12 is located at a side opposite to the processing module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the up and down direction, and is capable of independently moving forward and backward.

The processing module 20 includes a buffer unit 200, a transfer chamber 300, a liquid processing chamber 400, and a supercritical processing apparatus. The buffer unit 200 provides a space in which the substrate W loaded into the processing module 20 and the substrate W unloaded from the processing module 20 stay temporarily. The liquid processing chamber 400 performs a processing process of liquid-processing the substrate W by supplying a liquid onto the substrate W. The supercritical processing apparatus performs a drying process for removing a liquid remaining on the substrate W. The transfer chamber 300 transfers the substrate W between the buffer unit 200, the liquid processing chamber 400, and the supercritical processing apparatus.

The transfer chamber 300 may be provided so that a longitudinal direction is the first direction 92. The buffer unit 200 may be disposed between the index module 10 and the transfer chamber 300. The liquid processing chamber 400 and the supercritical processing apparatus may be disposed on a side portion of the transfer chamber 300. The liquid processing chamber 400 and the transfer chamber 300 may be disposed in the second direction 94. The supercritical processing apparatus and the transfer chamber 300 may be disposed in the second direction 94. The buffer unit 200 may be located at one end of the transfer chamber 300.

According to an example, the liquid processing chambers 400 may be disposed on opposite sides of the transfer chamber 300, the supercritical processing apparatuses may be disposed on opposite sides of the transfer chamber 300, and the liquid processing chambers 400 may be disposed closer to the buffer unit 200 than supercritical processing apparatuses. At one side of the transfer chamber 300, the liquid processing chambers 400 may be provided in an array of A×B (A and B are each 1 or a natural number larger than 1) in the first direction 92 and the third direction 96. Further, at one side of the transfer chamber 300, the supercritical processing apparatuses may be provided in a number of C×D (C and D are each 1 or a natural number larger than 1) may be provided along each of the first direction 92 and the third direction 96. Unlike the above description, only the liquid processing chambers 400 may be provided at one side of the transfer chamber 300, and only the supercritical processing apparatuses may be provided at the other side thereof.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the up and down direction, and is capable of independently moving forward and backward.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

The control module 30 may control the substrate processing apparatus 1. The control module 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a processing recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory. The control module 30 may control the index module 10 and the processing module 20.

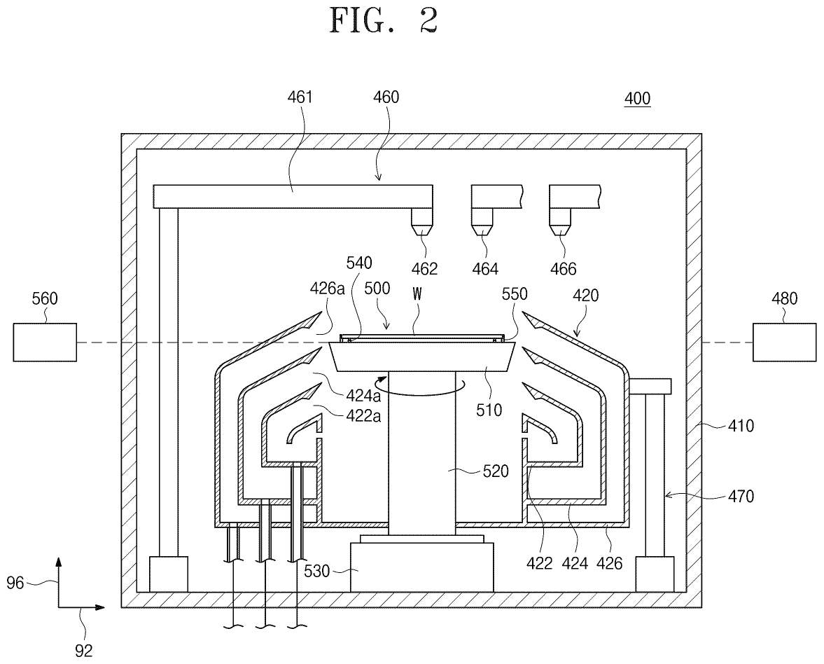

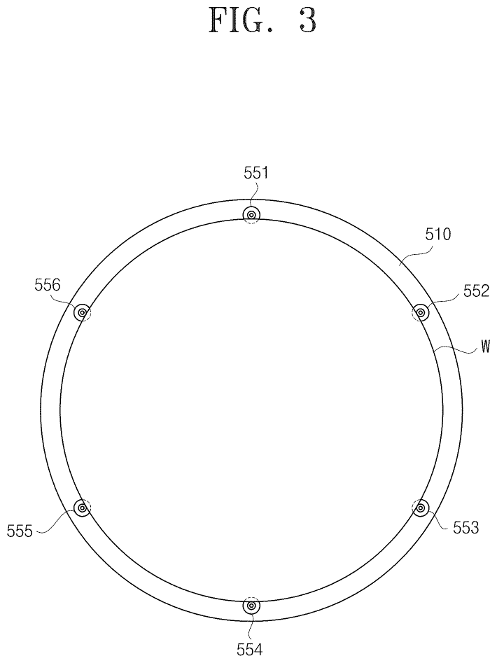

FIG. 2 is a top plan view of the liquid processing chamber provided in the substrate processing apparatus according to the exemplary embodiment of the present invention. FIG. 3 is a top plan view for describing a spin chuck according to the exemplary embodiment of the present invention.

Referring to FIG. 2, the liquid processing chamber 400 includes a housing 410, a cup 420, a spin chuck 500, a liquid supply unit 460, a lifting unit 470, and a controller 480. The housing 410 is provided in a generally rectangular parallelepiped shape. The cup 420, the spin chuck 500, and the liquid supply unit 460 are disposed within the housing 410.

The cup 420 has a processing space with an open top, and the substrate W is liquid-processed in the processing space. The spin chuck 500 supports the substrate W in the processing space. The liquid supply unit 460 supplies the liquid onto the substrate W supported on the spin chuck 500. The liquid may be provided in a plurality of types, and may be sequentially supplied onto the substrate W. The lifting unit 470 adjusts a relative height between the cup 420 and the spin chuck 500.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 500. As the liquid processing process proceeds, the processing liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the spin chuck 500, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

Referring to FIGS. 2 to 3, the spin chuck 500 supports and rotates the substrate W. The spin chuck 500 includes a body 510, a rotary shaft 520, a rotary shaft driver 530, a plurality of support pins 540, a plurality of chuck pins 550, and a chuck pin driver 560.

The body 510 is provided to have a circular plate shape. The body 510 is provided so that the upper and lower surfaces have different sizes. For example, the body 510 may be provided such that the lower surface has a circular shape having a smaller size than the upper surface. When viewed from the top, the upper and lower surfaces of the body 510 are positioned to have a concentric circle. The side surface of the body 510 may be provided to be inclined downward so as to approach the central axis of the body 510 from top to bottom.

The rotary shaft 520 is fixedly coupled to a bottom surface of the body 510. The rotary shaft 520 is rotated by the rotary shaft driver 530. For example, the rotary shaft driver 530 may be a motor.

A plurality of support pins 540 is disposed at the edges of the upper surface of the body 510. A plurality of support pins 540 are disposed to be spaced apart from each other at predetermined intervals. A plurality of support pins 540 is disposed to have an annular ring shape as a whole by combination therebetween. A plurality of support pins 540 protrude upward from the body 510. A plurality of support pins 540 supports the bottom edge of the substrate W so that the substrate W is spaced apart from the upper surface of the body 510 by a predetermined distance.

A plurality of chuck pins 550 is disposed to be farther from the center of the body 510 than the support pin 540. A plurality of chuck pins 550 is provided to protrude upward from the body 510. In FIG. 3, six chuck pins (first chuck pins 551 to sixth chuck pins) are illustrated as a plurality of chuck pins 550, but this is an example and the present invention is not limited thereto. A plurality of chuck pins 550 support side portions of the substrate W so that the substrate W is not separated from the correct position in the lateral direction when the spin chuck 500 rotates.

In the chuck pin driver 560, a plurality of chuck pins 550 linearly move between a standby position and a support position. A plurality of chuck pins 550 moves between the standby position and the support position in a radial direction of the body 510. The standby position is a position at which a space larger than the substrate W is provided so that the substrate W may be placed on the body 510, and the support position is a position at which a plurality of chuck pins 550 is in contact with a side portion of the substrate W during the process. Accordingly, the support position is a position closer to the center of the body 510 than the standby position. When a process for the substrate W is performed, a plurality of chuck pins 550 is positioned at the support position. A plurality of chuck pins 550 is in contact with the side portion of the substrate W at the support position and apply pressure to the substrate W.

Meanwhile, the substrate W may be a chuck diagnosis jig 600 for measuring a pressure value applied by a plurality of chuck pins 550 and displaying information on the measured pressure value.

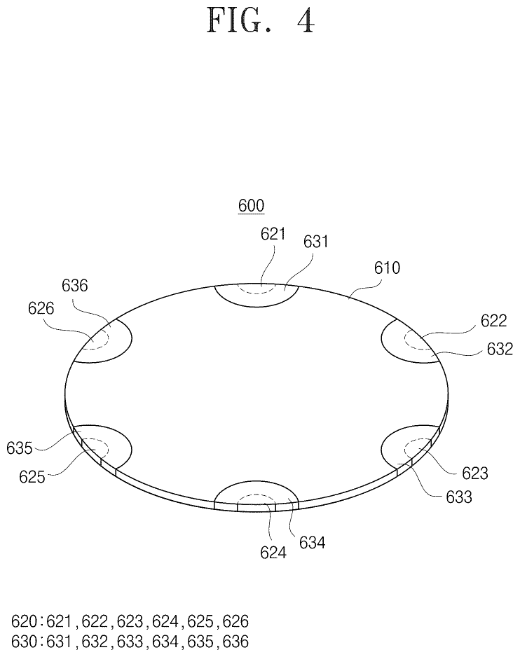

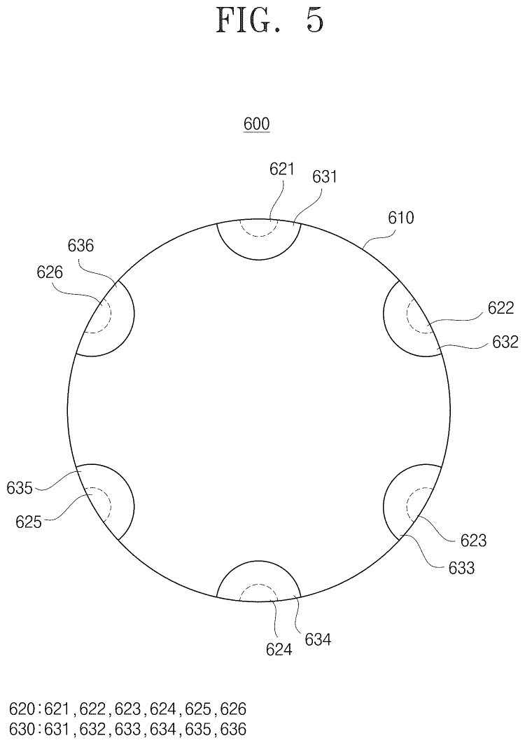

FIG. 4 is a perspective view of the chuck diagnosis jig according to the exemplary embodiment of the present invention. FIG. 5 is a top plan view of the chuck diagnosis jig according to the exemplary embodiment of the present invention.

Referring to FIGS. 4 to 5, the chuck diagnosis jig 600 includes a base part 610, a plurality of pressure sensors 620, and a plurality of display units 630.

The base part 610 is configured to be supported by the spin chuck 500. The diameter of the base part 610 may be the same as the diameter of the substrate W.

A plurality of pressure sensors 620 is provided at positions corresponding to the plurality of chuck pins 550, respectively. A position corresponding to the plurality of chuck pins 550 is a position on the base part 610 at which pressure is applied by each of the plurality of chuck pins 550, respectively. The number of plurality of pressure sensors 620 is the same as the number of plurality of chuck pins 550, and the plurality of pressure sensors 620 is provided at regular intervals along the circumferential direction of the base part 610. A plurality of pressure sensors 620 measures pressure values applied by the plurality of chuck pins 550 to the base part 610. For example, the plurality of pressure sensors 620 may be a plurality of pressure sensors of a resistive type or a plurality of pressure sensors of a capacitive type. The plurality of pressure sensors 620 transmit the pressure values to the controller 480.

For example, when six chuck pins (a first chuck pin 551 to a sixth chuck pin 556) are provided as illustrated in FIG. 3, a plurality of six pressure sensors (first to sixth pressure sensors 621 to 626) are provided at positions corresponding to the first chuck pin 551 to the sixth chuck pin 556. The first to sixth pressure sensors 621 to 626 may be provided at regular intervals along the circumferential direction of the base part 610. Each of the first to sixth pressure sensors 621 to 626 may measure a pressure value applied to the base part 610 by each of the first to sixth chuck pins 551 to 556, and transmit the measured pressure value to the controller 480.

The plurality of display units 630 is provided at positions corresponding to the plurality of pressure sensors 620. The plurality of pressure sensors 620 is installed in the area where the plurality of display units 630 is provided. The number of plurality of display units 630 is the same as the number of the plurality of pressure sensors 620, and the plurality of display units 630 is provided at regular intervals along the circumferential direction of the base part 610. For example, the plurality of display units 630 may be light emitting members and may display different colors.

When six pressure sensors (first to sixth pressure sensors 621 to 626) are provided as illustrated in FIG. 4, six display units (first to sixth display units 631 to 636) are provided at positions corresponding to the first to sixth pressure sensors 621 to 626. The first to sixth display units 631 to 636 are provided at regular intervals along the circumferential direction. The first to sixth display units 631 to 636 may display colors, respectively.

Referring back to FIG. 2, the lifting unit 470 moves the cup 420 in the up and down direction. By the up and down movement of the cup 420, a relative height between the cup 420 and the substrate W is changed. Accordingly, the recovery containers 422, 424, and 426 for recovering the processing liquid are changed according to the type of liquid supplied to the substrate W, and thus the liquids may be separated and recovered. Unlike the description, the cup 420 is fixedly installed, and the lifting unit 470 may move the spin chuck 500 in the up and down direction.

The controller 480 is configured in the same manner as the control module 30 of FIG. 1. The controller 480 controls the spin chuck 500, the liquid supply unit 460, the lifting unit 470, and the chuck diagnosis jig 600.

The controller 480 controls the chuck pin driver 560 such that the plurality of chuck pins 550 moves from the standby position to the support position or from the support position to the standby position. The controller 480 controls the rotary shaft driver 530 such that the rotary shaft 520 in the stationary state rotates or the rotating rotary shaft 520 stops.

When the chuck diagnosis jig 600 is placed on the body 510, the controller 480 may control the plurality of pressure sensors 620 to measure a pressure value applied to the base part 610 by each of the plurality of chuck pins 550. The controller 480 may receive the plurality of pressure values from the plurality of pressure sensors 620.

The controller 480 controls the plurality of display units 640 based on the plurality of pressure values. The controller 480 matches the plurality of pressure values with a preset color. Here, the preset color may be based on a range of pressure values. For example, a first color is matched when the pressure value is in a first range lower than the pressure value in the normal state, a second color is matched when the pressure value is in a second range, which is the pressure value in the normal state, a third color is matched when the pressure value is in a third range higher than the pressure value in the normal state, and a fourth color is matched when the pressure value is in a fourth range much higher than the pressure value in the normal state.

Here, the first range may be a range of pressure values in which the substrate W may be deviated from the correct position on the body when the spin chuck 500 rotates in a range of pressure values in which the substrate W is not normally supported by the chuck pin 550, the second range may be a range of pressure values in which the substrate W is normally supported by the chuck pin 550, and is a range of pressure values in which the substrate W is supported without being separated from the correct position on the body 510, and damage is not applied by the plurality of chuck pins 550, and the third and fourth ranges may be ranges of pressure values in which the substrate W is not normally supported by the chuck pin 550, and may be a range of pressure values in which damage may be applied by the plurality of chuck pins 550. The controller 480 controls the plurality of display units 630 to display the matched colors.

The controller 480 performs diagnosis on the plurality of chuck pins 550 based on the plurality of pressure values, and controls the spin chuck 500 and the plurality of display units 630 based on a result of the diagnosis.

In the exemplary embodiment, the controller 480 determines whether there is a chuck pin 550 that needs to be replaced among the plurality of chuck pins 550 by comparing the plurality of pressure values with a preset value. For example, when the pressure value falls within the first range, the third range, or the fourth range, the controller 480 determines that the chuck pin 550 to which the corresponding pressure value is applied needs to be replaced, and the chuck pin 550 may be replaced.

When it is determined that the plurality of chuck pins 550 are all required to be replaced, the controller 480 controls the chuck pin driver 560 such that the pressure value applied to the base part 610 by the plurality of chuck pins 550 becomes a normal state. For example, the pressure value in the normal state may be the pressure value in the second range.

Furthermore, the controller 480 determines whether slip has occurred in each of the plurality of chuck pins 550 based on the plurality of pressure values. Although the controller 480 determines that the spin chuck 500 is in a normal state before the spin chuck 500 rotates, when the chuck pin 550 whose pressure value is not the normal state exists after the spin chuck 500 rotates, the controller 480 determines that the chuck pin 550 has slipped. When the chuck pin 550 at which slip has occurred is present among the plurality of chuck pins 550, the controller 480 makes a control on the mounting position of the chuck pin 550 at which slip has occurred. In this case, the mounting position of the corresponding chuck pin 550 is changed to a normal position, which is a position before slip occurs.

For example, when there is a chuck pin 550 whose pressure value is in the second range before the spin chuck 500 rotates, but whose pressure value is in the first range after the spin chuck 500 rotates, the controller 480 may determine that slip has occurred in the corresponding chuck pin 550, and the mounting position of the corresponding chuck pin 50 may be changed to a normal position.

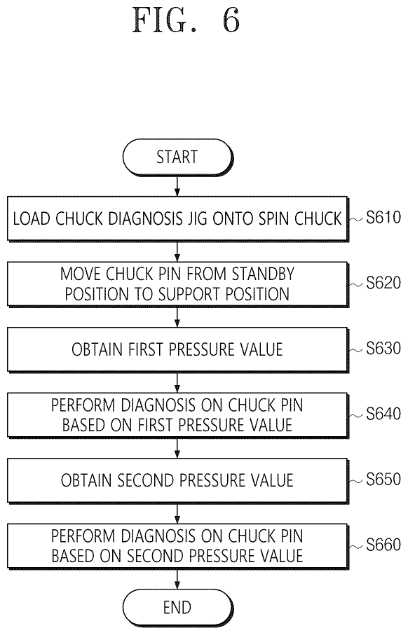

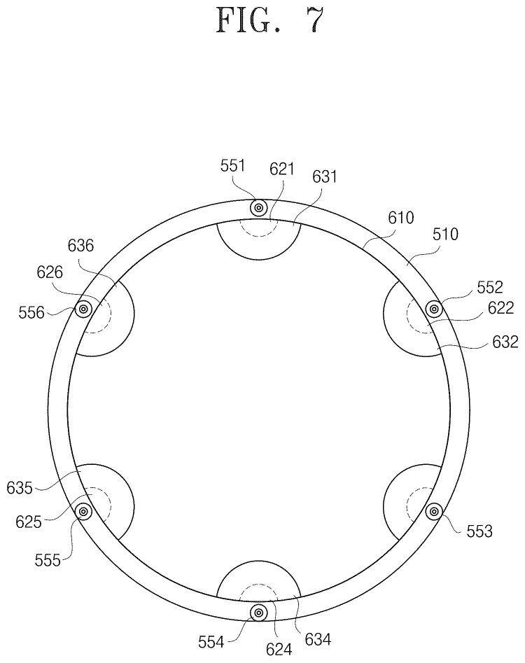

FIG. 6 is a flowchart of a diagnosis method according to an exemplary embodiment of the present invention. FIGS. 7 to 14 are diagrams for describing the diagnosis method according to the exemplary embodiment of the present invention.

Referring to FIG. 6, the substrate processing apparatus loads the chuck diagnosis jig onto the spin chuck (S610). Step S610 is performed by the transfer robot 320 of the transfer chamber 300 disposed adjacent to the liquid processing chamber 400. Referring to FIG. 7, the chuck diagnosis jig 600 is seated on the body 510 of the spin chuck 500. In this case, a plurality of chuck pins 550 is positioned at the standby position.

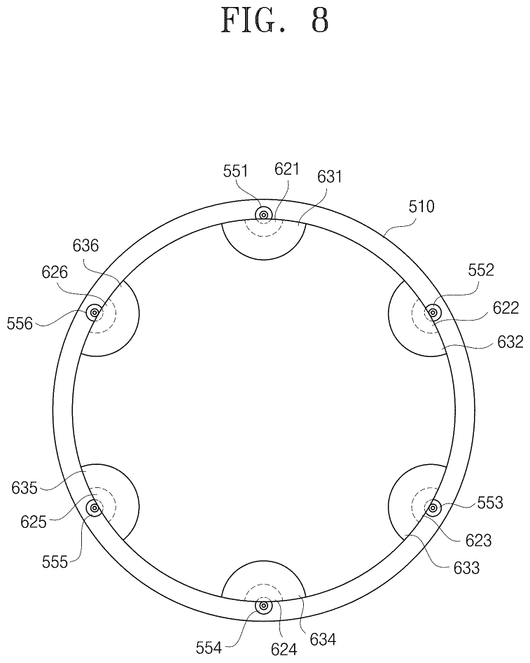

The substrate processing apparatus moves the chuck pin from the standby position to the support position (S620). Referring to FIG. 8, the controller 480 controls the chuck pin driver 560 to move the plurality of chuck pins 550 from the standby position to the support position. The plurality of chuck pins 550 moves from the standby position to the support position. The plurality of chuck pins 550 supports the chuck diagnosis jig 600. The plurality of chuck pins 550 applies pressure values to the base part 610 of the chuck diagnosis jig 600. The first chuck pin 551 to the sixth chuck pin 556 respectively apply pressure values to the base part 610.

The substrate processing apparatus obtains a plurality of first pressure values (S630). The controller 480 controls the plurality of pressure sensors 620 to measure a first pressure value applied to the base part 610 by the plurality of chuck pins 550. The controller 480 controls each of the first to sixth pressure sensors 621 to 626 to measure a first pressure value applied to the base part 610 by each of the first to sixth chuck pins 551 to 556.

The plurality of pressure sensors 620 measures a pressure value applied to the base part 610 by the plurality of chuck pins 550, and transmit the plurality of measured first pressure values to the controller 480. That is, the first pressure sensor 621 to the sixth pressure sensor 626 measure a first pressure value applied to the base part 610 by the first chuck pin 551 to the sixth chuck pin 556, respectively, and transmit the measured first pressure values to the controller 480.

The substrate processing apparatus performs diagnosis on the plurality of chuck pins based on the plurality of first pressure values (S640). The controller 480 receives the plurality of first pressure values from the plurality of pressure sensors 620. The controller 480 receives the first pressure values from the first to sixth pressure sensors 621 to 626, respectively. The controller 480 matches colors corresponding to the plurality of first pressure values. The controller 480 matches colors corresponding to the first pressure values measured by the first to sixth pressure sensors 621 to 626.

The controller 480 controls the plurality of display units 630 to display the matched colors. The controller 480 controls the first to sixth display units 631 to 636 to display colors corresponding to the first pressure values measured by the first to sixth pressure sensors 626. The plurality of display units 630 displays colors corresponding to the plurality of first pressure values. The first to sixth display units 631 to 636 display colors corresponding to the first pressure values measured by the first to sixth pressure sensors 621 to 626.

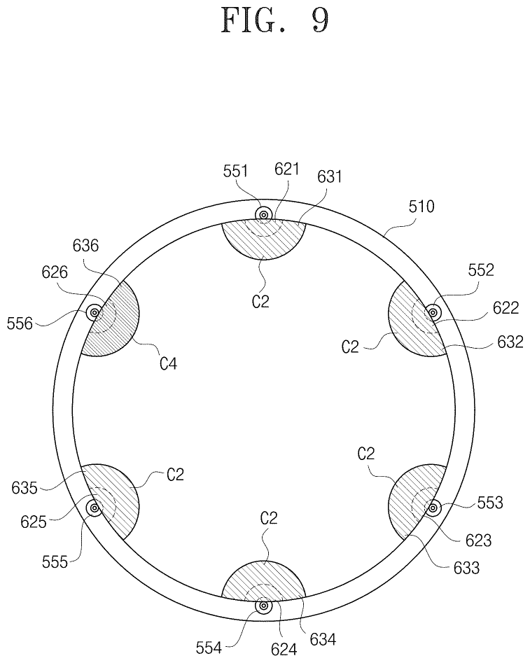

Referring to FIG. 9, for example, when the first pressure values measured by the first pressure sensor 621 to the fifth pressure sensor 625 fall within the second range and the first pressure value measured by the sixth pressure sensor 626 falls within the fourth range, the first to fifth display units 631 to 635 display the second color C2 and the sixth display unit 636 displays the fourth color C4.

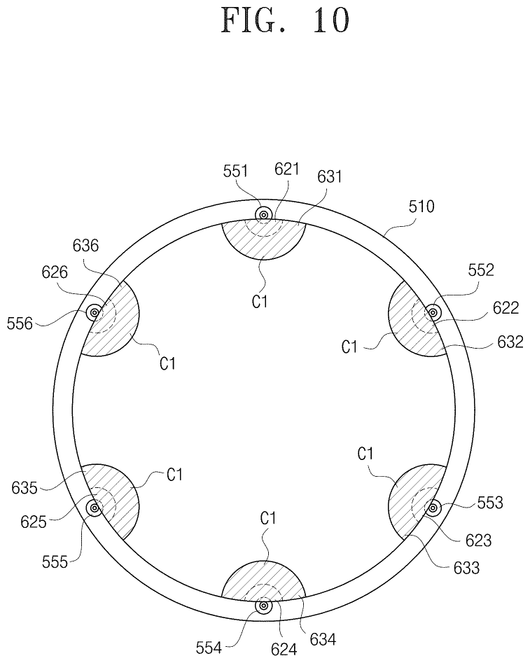

Referring to FIG. 10, for example, when the first pressure values measured by the first pressure sensor 621 to the sixth pressure sensor 626 fall within the first range, the first to sixth display units 631 to 636 display the first color C1.

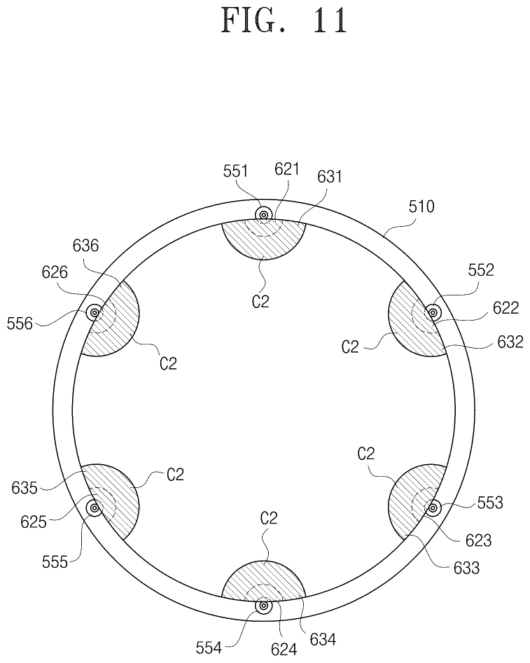

Referring to FIG. 11, for example, when the first pressure values measured by the first pressure sensor 621 to the sixth pressure sensor 626 fall within the second range, the first to sixth display units 631 to 636 display the second color C2.

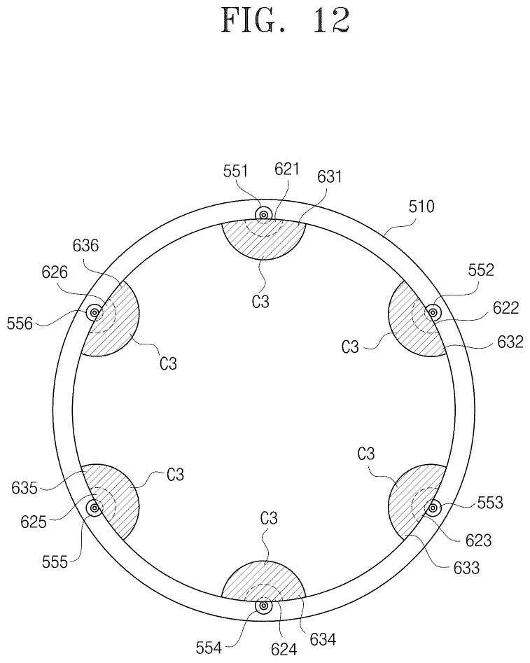

Referring to FIG. 12, for example, when the first pressure values measured by the first pressure sensor 621 to the sixth pressure sensor 626 fall within the third range, the first to sixth display units 631 to 636 display the third color C3.

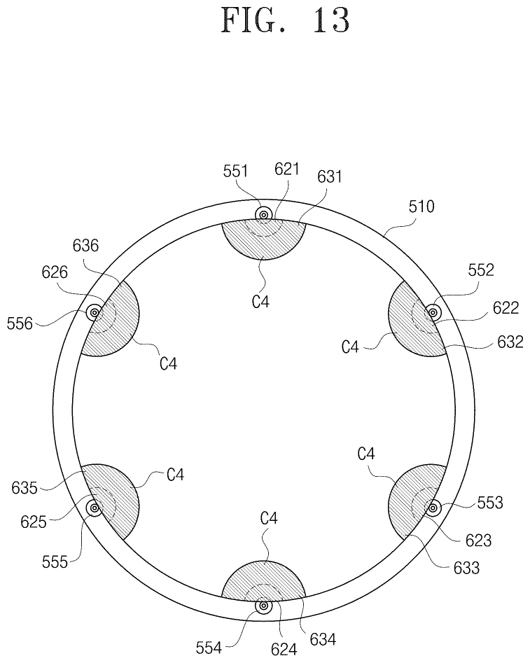

Referring to FIG. 13, for example, when the first pressure values measured by the first pressure sensor 621 to the sixth pressure sensor 626 fall within the fourth range, the first to sixth display units 631 to 636 display the fourth color C4.

The controller 480 determines whether there is a chuck pin 550 that needs to be replaced among the plurality of chuck pins 550 based on the plurality of pressure values. The controller 480 compares the plurality of first pressure values with a preset value to determine whether there is a chuck pin 550 that needs to be replaced among the plurality of chuck pins 550. For example, the controller 480 determines whether there is a first pressure value corresponding to the first range, the second range, or the fourth range among the first pressure values measured by the first to sixth pressure sensors 626. The controller 480 determines that the chuck pin 550 which applies the first pressure value corresponding to the first range, the second range, or the fourth range among the plurality of chuck pins 550 needs to be replaced.

When the controller 480 determines that a portion of the chuck pins 550 need to be replaced, the corresponding chuck pin 550 may be replaced. For example, replacement of the chuck pin 550 may be performed by an operator, but the present invention is not limited thereto.

For example, when the first pressure values measured by the first pressure sensor 621 to the fifth pressure sensor 621 fall within the second range and the first pressure value measured by the sixth pressure sensor 626 falls within the fourth range, the controller 480 determines that the sixth chuck pin 556 among the plurality of chuck pins 550 needs to be replaced. In this case, the sixth chuck pin 556 is replaced.

When it is determined that all of the plurality of chuck pins 550 need to be replaced, the controller 480 controls the chuck pin driver 560. The controller 480 controls the chuck pin driver 560 such that the pressure value applied to the base part 610 by the plurality of chuck pins 550 becomes a normal state. The chuck pin driver 560 drives the plurality of chuck pins 550 such that the pressure value applied by the plurality of chuck pins 550 becomes a normal state.

For example, when the first pressure values measured by the first to sixth pressure sensors 621 to 626 fall within the first range as illustrated in FIG. 10, the controller 480 controls the chuck pin driver 560 such that the pressure values applied by the first to sixth chuck pins 551 to 556 fall within the second range. The chuck pin driver 560 drives the plurality of chuck pins 550 such that the pressure values applied by the first to sixth chuck pins 551 to 556 fall within the second range.

For example, when the first pressure values measured by the first to sixth pressure sensors 621 to 626 fall within the third range as illustrated in FIG. 12, the controller 480 controls the chuck pin driver 560 such that the pressure values applied by the first to sixth chuck pins 551 to 556 fall within the second range. The chuck pin driver 560 drives the plurality of chuck pins 550 such that the pressure values applied by the first to sixth chuck pins 551 to 556 fall within the second range.

For example, when the first pressure values measured by the first to sixth pressure sensors 621 to 626 fall within the fourth range as illustrated in FIG. 13, the controller 480 controls the chuck pin driver 560 such that the pressure values applied by the first to sixth chuck pins 551 to 556 fall within the second range. The chuck pin driver 560 drives the plurality of chuck pins 550 such that the pressure values applied by the first to sixth chuck pins 551 to 556 fall within the second range.

The substrate processing apparatus obtains a plurality of second pressure values (S650). The controller 480 controls the rotary shaft driver 530 so that the rotary shaft 520 rotates. The rotary shaft driver 530 rotates the rotary shaft 520, whereby the body 510 connected to the rotary shaft 520 rotates. Pressure applied to the base part 610 by the plurality of chuck pins 550 before the body 510 rotates is a pressure value in a normal state.

The controller 480 controls the plurality of pressure sensors 620 to measure a second pressure value applied to the base part 610 by the plurality of chuck pins 550. The controller 480 controls each of the first to sixth pressure sensors 621 to 626 to measure a second pressure value applied to the base part 610 by each of the first to sixth chuck pins 551 to 556.

The plurality of pressure sensors 620 measures pressure values applied to the base part 610 by the plurality of chuck pins 550, and transmits a plurality of measured second pressure values to the controller 480. That is, the first to sixth pressure sensors 621 to 626 measure second pressure values applied to the base part 610 by the first to sixth chuck pins 551 to 556, respectively, and transmit the measured second pressure value to the controller 480.

The substrate processing apparatus performs diagnosis on the plurality of chuck pins based on the plurality of second pressure values (S660). The controller 480 receives the plurality of second pressure values from the plurality of pressure sensors 620. The controller 480 matches colors corresponding to the plurality of second pressure values in the same manner as described in S640, and controls the plurality of display units 630 to display the matched colors.

The controller 480 determines whether slip has occurred in the plurality of chuck pins 550 based on the plurality of second pressure values. For example, the controller 480 determines whether there is a second pressure value corresponding to the first range, the second range, or the fourth range among the second pressure values measured by the first to sixth pressure sensors 626. The controller 480 determines that slip occurs in the chuck pin 550 which applies the second pressure value corresponding to the first range, the second range, or the fourth range among the plurality of chuck pins 550. That is, the controller 480 determines that slip occurs in the chuck pin 550 which applies a normal pressure value to the base part 610 before the body 510 rotates, but applies a non-normal pressure value to the base part 610 after the body 510 rotates.

When there is a cuck pin 550 in which the slip occurs, the controller 480 controls the mounting position of the corresponding chuck pin 550. The mounting position of the chuck pin 550 is controlled so that the mounting position of the chuck pin 550 is changed to a normal position, which is a position before the slip occurs. The control on the mounting position of the chuck pin 550 may be performed by an operator, but the present invention is not limited thereto.

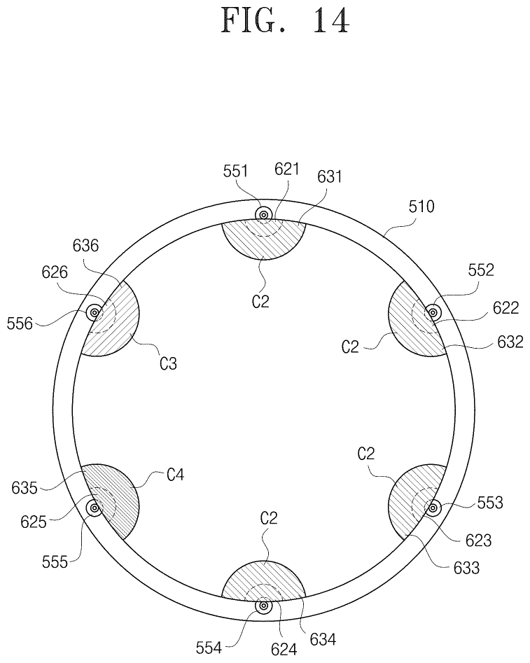

Referring to FIG. 14, for example, when the second pressure values measured by the first to fourth pressure sensors 621 to 624 fall within the second range, the second pressure value measured by the fifth pressure sensor 625 falls within the third range, and the second pressure value measured by the sixth pressure sensor 626 falls within the fourth range, the controller 480 determines that slip occurs in the fifth chuck pin 555 and the sixth chuck pin 556 among the plurality of chuck pins 550. In this case, the mounting positions of the fifth chuck pin 555 and the sixth chuck pin 556 are changed to normal positions.

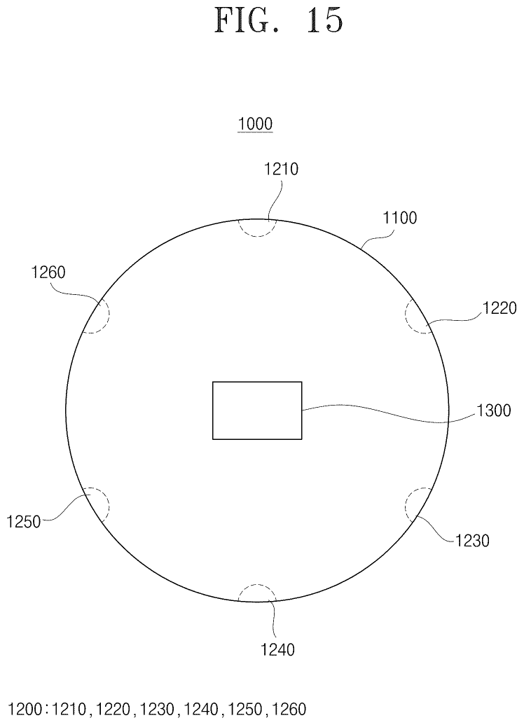

FIG. 15 is a top plan view of a chuck diagnosis jig according to another exemplary embodiment of the present invention.

Referring to FIG. 15, a chuck diagnosis jig 1000 according to another exemplary embodiment of the present invention includes a base part 1100, a plurality of pressure sensors 1200, and a display unit 1300. The base part 1100 and the plurality of pressure sensors 1200 are the same as the base part 610 and the plurality of pressure sensors 620 of the chuck diagnosis jig 600 described above. The display unit 1300 is provided at a center of the base part 1100. The display unit 1300 displays a plurality of pressure values measured by the plurality of pressure sensors 1200. For example, the display unit 1300 may display the pressure values measured by the plurality of pressure sensors 1200 in a range, color, or number.

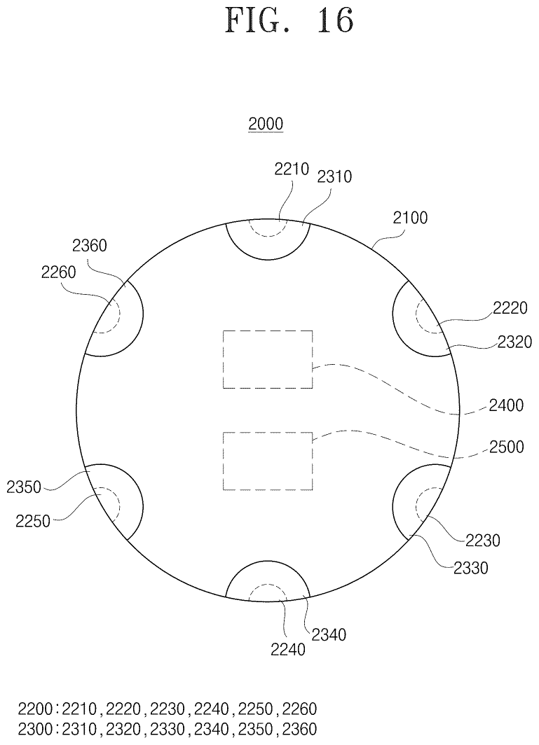

FIG. 16 is a top plan view of a chuck diagnosis jig according to still another exemplary embodiment of the present invention.

Referring to FIG. 16, a chuck diagnosis jig 2000 according to another exemplary embodiment of the present invention includes a base part 2100, a plurality of pressure sensors 2200, a plurality of display units 2300, a communication unit 240, and a control module 30.

The base part 2100, the plurality of pressure sensors 2200, and the plurality of display units 2300 are the same as the base part 610, the plurality of pressure sensors 620, and the plurality of display units 2300 of the chuck diagnosis jig 600 described above. Alternatively, the plurality of display units 2300 may be configured as a single display unit 1300 as illustrated in FIG. 14.

The communication unit 2400 communicates with the controller 480 of the liquid processing chamber 400 and the controller 2500. For example, the communication unit 2400 may perform communication by a manner, such as Wireless LAN (WLAN), Bluetooth (BT), Zigbee, Z-Wave, Ultra Wide Band (UWB), Ultra Narrow Band (UNB), WirelessUSB, Wireless Gigabit (WiGig), Bluetooth Low Energy (BLE), 3rd generation (3G), Long Term Evolution (LTE), or New Radio (NR).

The communication unit 2400 receives pressure values from the plurality of pressure sensors 2200. The communication unit 2400 transmits a plurality of pressure values to at least one of the controller 480 and the controller 2500. Furthermore, the communication unit 2400 may receive commands regarding the plurality of pressure sensors 2200 or the plurality of display units 2300 from the controller 480. The communication unit 2400 transmits commands regarding the plurality of pressure sensors 2200 or the plurality of display units 2300 to the controller 2500.

The control unit 2500 receives the plurality of pressure values from the communication unit 2400. The control unit 2500 controls the plurality of display units 2300 based on the plurality of pressure values. Furthermore, the control unit 2500 receives a command regarding the plurality of pressure sensors 2200 or the plurality of display units 2300 from the communication unit 2400, and controls the plurality of pressure sensors 2200 or the plurality of display units 2300 according to the corresponding command.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a cup having a processing space with an open top;
a spin chuck for supporting the substrate within the processing space;
a liquid supply nozzle for supplying a processing liquid to the substrate supported on the spin chuck; and
a chuck diagnosis jig for diagnosing a state of the spin chuck,
wherein the spin chuck includes:
a body coupled to a rotary shaft;
a plurality of chuck pins installed on the body and supporting a side of the substrate during a process; and
a chuck pin driver for moving the plurality of chuck pins between a support position in which the plurality of chuck pins is in contact with an end of the substrate placed on the spin chuck and a standby position in which the plurality of chuck pins is spaced apart from the end of the substrate placed on the spin chuck, and
the chuck diagnosis jig includes:
a base part supportable by the spin chuck; and
a pressure sensor for measuring a pressure value applied to the base part by the chuck pin when the plurality of chuck pins is driven from the standby position to the support position in a state where the chuck diagnosis jig is placed on the spin chuck.

2. The apparatus of claim 1, wherein the base part has the same diameter as the substrate supported on the spin chuck.

3. The apparatus of claim 1, wherein the pressure sensors are provided at positions corresponding to the plurality of chuck pins in a number equal to a number of the plurality of chuck pins.

4. The apparatus of claim 3, wherein the chuck diagnosis jig further includes a display unit provided on the base part.

5. The apparatus of claim 4, wherein the display units are provided in a number equal to the number of the plurality of pressure sensors, and
the plurality of pressure sensors is installed in areas in which the plurality of display units is provided, respectively.

6. The apparatus of claim 5, wherein the plurality of pressure sensors and the plurality of display units are provided at regular intervals along a circumferential direction of the base part.

7. The apparatus of claim 4, further comprising:
a controller for receiving a pressure value applied to the base part by each of the plurality of chuck pins from the plurality of pressure sensors and controlling the spin chuck and the display unit based on the plurality of pressure values.

8. The apparatus of claim 7, wherein the controller matches different colors according to magnitudes of the plurality of pressure values, and
controls the display unit to display the matched color.

9. The apparatus of claim 7, wherein the controller compares the plurality of pressure values with a preset value to determine whether there is a chuck pin that needs to be replaced among the plurality of chuck pins,
controls the chuck pin driver when it is determined that all of the plurality of chuck pins need to be replaced, and,
replaces a portion of the chuck pins or controls mounting positions of the portion of the chuck pins when it is determined that the portion of the plurality of chuck pins needs to be replaced.

10. The apparatus of claim 4, wherein the display unit is provided at a center of the base part.

11. The apparatus of claim 1, wherein the pressure sensor is a resistive type pressure sensor or a capacitive type pressure sensor.

12-16. (canceled)

17. An apparatus for processing a substrate, the apparatus comprising:
a cup having a processing space with an open top;
a spin chuck for supporting the substrate within the processing space;
a liquid supply nozzle for supplying a processing liquid to the substrate supported on the spin chuck;
a chuck diagnosis jig for diagnosing a state of the spin chuck; and
a controller for controlling the spin chuck and the chuck diagnosis jig,
wherein the spin chuck includes:
a body coupled to a rotary shaft;
a plurality of chuck pins installed on the body and supporting a side of the substrate during a process; and
a chuck pin driver for moving the plurality of chuck pins between a support position in which the plurality of chuck pins is in contact with an end of the substrate placed on the spin chuck and a standby position in which the plurality of chuck pins is spaced apart from the end of the substrate placed on the spin chuck, and
the chuck diagnosis jig includes:
a base part supportable by the spin chuck; and
a pressure sensor for measuring a pressure value applied to the base part by the chuck pin when the plurality of chuck pins is driven from the standby position to the support position in a state where the chuck diagnosis jig is placed on the spin chuck; and
a display unit provided in the base part,
the base part has the same diameter as the substrate supported on the spin chuck,
the pressure sensors are provided at positions corresponding to the plurality of chuck pins in a number equal to a number of the plurality of chuck pins,
the display units are provided in a number corresponding a number of the plurality of pressure sensors,
the plurality of pressure sensors is installed in areas in which the plurality of display units is provided, respectively,
the plurality of pressure sensors and the plurality of display units are provided at regular intervals along a circumferential direction of the base part, and
a controller receives a pressure value applied to the base part by each of the plurality of chuck pins from the plurality of pressure sensors and controls the spin chuck and the chuck diagnosis jig based on the plurality of pressure values.

18. The apparatus of claim 17, wherein the controller matches different colors according to magnitudes of the plurality of pressure values, and
controls the display unit to display the matched color.

19. The apparatus of claim 17, wherein the controller compares the plurality of pressure values with a preset value to determine whether there is a chuck pin that needs to be replaced among the plurality of chuck pins,
controls on the chuck pin driver when it is determined that all of the plurality of chuck pins need to be replaced, and,
replaces a portion of the chuck pins or controls a mounting position of the portion of the chuck pins when it is determined that the portion of the plurality of chuck pins need to be replaced.

20. The apparatus of claim 17, wherein the controller controls the spin chuck so that the spin chuck rotates,
receives a pressure value applied to the base part by the plurality of chuck pins from the plurality of pressure sensors when the spin chuck rotates,
determines whether slip occurs in the plurality of chuck pins based on the plurality of pressure values, and
controls a mounting position of at least one chuck pin when the slip occurs in the at least one of the plurality of chuck pins.
